(19) United States
(12) Patent Application Publication
(10) Pub. No.: US 2013/0098675 A1
(43) Pub. Date: Apr. 25, 2013

(54) METHOD AND APPARATUS FOR APPLICATION OF ANTI-STICTION COATING

(71) Applicants: Jan Bos, Hsinchu (TW); David Heald, Solvang, CA (US); Yen Hua Lin, Taoyuan Hsien (CN); Yung-Wei Lai, Jhongli City (TW); Jui-Chih Liao, Chiayi City (TW); Yoke-Hou Tan, Taipei City (TW); Nageswara Tadepalli, San Jose, CA (US); Yan Du, Fremont, CA (US); Jianwei Liu, San Jose, CA (US); Richard Pietri, San Jose, CA (US)

(72) Inventors: Jan Bos, Hsinchu (TW); David Heald, Solvang, CA (US); Yen Hua Lin, Taoyuan Hsien (CN); Yung-Wei Lai, Jhongli City (TW); Jui-Chih Liao, Chiayi City (TW); Yoke-Hou Tan, Taipei City (TW); Nageswara Tadepalli, San Jose, CA (US); Yan Du, Fremont, CA (US); Jianwei Liu, San Jose, CA (US); Richard Pietri, San Jose, CA (US)

(73) Assignee: QUALCOMM MEMS Technologies, Inc., San Diego, CA (US)

(21) Appl. No.: 13/279,132

(22) Filed: Oct. 21, 2011

(51) Int. Cl. H05K 7/00; B05D 5/12

(52) U.S. Cl. 174/520; 427/100

(57) ABSTRACT

This disclosure provides apparatus, systems and methods for manufacturing electromechanical systems (EMS) packages. One method includes making an EMS package that includes an out-gassable anti-stiction coating. The anti-stiction coating may be a solvent that is included within part of a desiccant mixture. In some implementations, the method includes sealing an EMS device into a package and then heating the package using a temperature profile that out-gasses at least a portion of a residual solvent. The method may include an incubation bake cycle to distribute anti stiction material to display elements within the EMS package. The incubation bake cycle may also more evenly distribute contaminants within the EMS package so as to reduce their effects.

### TECHNICAL FIELD

This disclosure relates to electromechanical systems. More specifically, this disclosure relates to electromechanical systems that include a desiccant to control the environment within an electromechanical systems package.

### DESCRIPTION OF THE RELATED TECHNOLOGY

Electromechanical systems (EMS) include devices having electrical and mechanical elements, actuators, transducers, sensors, optical components (including mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is an interferometric modulator (IMOD). As used herein, the term interferometric modulator, or interferometric light modulator, refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

The ability to control the moisture level in electromechanical systems devices may be important for the consistent performance and lifetime of the device. For example, in MEMS contact capacitive switches, a low humidity packaged environment may be necessary to avoid, e.g., capillary force-induced adhesion of the contacting surfaces. Even slight variations of the humidity level, on the order of 10's of parts per million (ppm), may lead to variations in device performance caused by charging of the contact surfaces or alteration of the surface chemical environment. To control the moisture level of a package where a hermetic seal is not an option, a desiccant may be employed.

### SUMMARY

The systems, methods and devices of the disclosure each have several innovative aspects, no single one of which is solely responsible for the desirable attributes disclosed herein.

One innovative aspect of the subject matter described in this disclosure can be implemented in a method of making an electromechanical systems (EMS) package having an anti-stiction coating, the method including placing an out-gassable anti-stiction material into the EMS package, the EMS package having at least one movable surface, sealing the EMS package, and releasing the anti-stiction material within the EMS package to coat the at least one movable surface with the anti-stiction material. In some implementations, placing an out-gassable anti-stiction material into the EMS package includes placing a desiccant into the EMS package. In some other implementations, the desiccant includes the out-gassable anti-stiction material. In some implementations, the anti-stiction material is a solvent used in the manufacturing of the desiccant.

In some implementations, the method includes heating the desiccant with a first temperature profile that leaves some residual anti-stiction material in the desiccant mixture. In some implementations, releasing the anti-stiction material includes heating the device package using a second temperature profile that causes out-gassing of at least a portion of the residual anti-stiction material from the desiccant. In some other implementations, the out-gassable anti-stiction material is a linear, branched, or cyclic non-polar hydrocarbon with 20 or less carbon atoms. In some implementations, the anti-stiction material is an isoparaffinic solvent. In some implementations, releasing the anti-stiction material within the EMS package includes an incubation bake at between of 90° C. and 120° C. for at least 24 hours.

In some other implementations, releasing the anti-stiction material within the EMS package includes an incubation bake of between 50° C. and 75° C. for at least 48 hours. In some other implementations, releasing the anti-stiction material within the EMS package includes an incubation bake configured to out-gas at least 90% of the anti-stiction material in the desiccant.

Another innovative aspect of the subject matter described in this disclosure can be implemented in an EMS package. The EMS package includes a sealed enclosure, an electromechanical systems device within the sealed enclosure, and a desiccant composition including a solvent having anti-stiction properties when vaporized.

In some implementations, the desiccant is a baked desiccant that has out-gassed a portion of the solvent. In some implementations, the solvent is a non-polar hydrocarbon. In some implementations, the sealed enclosure includes a backplate, and the desiccant is attached to the backplate. In some implementations, the desiccant is deposited within a cavity in the backplate. In some implementations, the desiccant is deposited on the backplate in a ring configuration.

Another innovative aspect of the subject matter described in this disclosure also can be implemented in an EMS package. The EMS package including a sealed enclosure, a desiccant within the sealed enclosure, and an EMS device within the sealed enclosure, the EMS device having at least one movable member, wherein the at least one movable member is coated with an anti-stiction coating formed from vaporizing a solvent included in a desiccant. In some implementations, the solvent is a non-polar hydrocarbon. In some implementations, the sealed enclosure includes a backplate, and wherein the desiccant is attached to the backplate. In some implementations the backplate has a cavity and wherein the desiccant is deposited or attached within the cavity. In some implementations, the desiccant is deposited or attached on the backplate as a ring that surrounds the EMS device.

In some implementations, the EMS package also includes a display, a processor that is configured to communicate with the display, the processor being configured to process image data, and a memory device that is configured to communicate with the processor. In some implementations, the EMS package also includes a driver circuit configured to send at least one signal to the display, and a controller configured to send at least a portion of the image data to the driver circuit. In some implementations, the EMS package also includes an image source module configured to send the image data to the processor, wherein the image source module includes at least one of a receiver, transceiver, and transmitter. In some implementations, the EMS package also includes an input device configured to receive input data and to communicate the input data to the processor.

In some implementations, the solvent is vaporized by an incubation bake of between 90° C. and 120° C. for at least 24 hours. In other implementations, the solvent is vaporized by an incubation bake of between 50° C. and 75° C. for at least 48 hours.

Another innovative aspect of the subject matter described in this disclosure can be implemented in an EMS package, including a sealed enclosure, an EMS device within the sealed enclosure, and means for releasing a solvent having anti-stiction properties into the sealed enclosure. In some implementations, the means for releasing a solvent is a desiccant. The means for releasing the solvent can be configured to release the solvent during an incubation bake of between 50° C. and 75° C. for at least 48 hours. In some other implementations, the solvent is a non-polar hydrocarbon. The means for releasing the solvent can also be configured to release the solvent during an incubation bake of between 90° C. and 120° C. for at least 24 hours.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIGS. 1A and 1B show examples of isometric views depicting a pixel of an interferometric modulator (IMOD) display device in two different states.

FIG. 2 is an example of a schematic partial cross-section illustrating one implementation of the structure of a driving circuit and an associated display element.

FIG. 3 shows an example of a schematic exploded partial perspective view of an optical MEMS display device having an interferometric modulator array and a backplate with embedded circuitry.

FIGS. 4A and 4B show examples of schematic exploded partial perspective views of a portion of an electromechanical systems (EMS) package including an array of electromechanical systems elements and a backplate.

FIG. 5 illustrates a method for making an EMS package.

FIG. 6 illustrates another method for making an EMS package.

FIG. 7 shows a perspective view of an EMS package including a desiccant within a sealed enclosure formed by a backplate and a substrate.

FIG. 8 shows a cross-sectional view of an assembled EMS package employing a desiccant within a sealed enclosure, with the desiccant including out-gassable anti-stiction material.

FIG. 9 shows another cross-sectional view of one implementation of the assembled EMS package employing a desiccant with out-gassable anti-stiction material within a sealed enclosure.

FIG. 10 shows a perspective view of an EMS package including a desiccant ring on a backplate that is configured to attach to a substrate.

FIG. 11 shows a cross-sectional view of an EMS package after an anti stiction material has been out-gassed from a desiccant.

FIGS. 12A and 12B show exploded views of an EMS package that detail the vapor paths of out-gassed anti stiction material from a desiccant on a backplate to a substrate within an EMS package.

FIG. 13 shows a top view illustration of an EMS package that has desiccant material arranged around the periphery of the EMS package and was not treated after packaging to reduce stiction.

FIG. 14 shows a top view illustration of an EMS package that has desiccant material arranged around the periphery of the EMS package and was treated after packaging to improve distribution of anti-stiction material.

FIGS. 15A and 15B show examples of system block diagrams of a display device that includes a plurality of interferometric modulators.

FIG. 16 is an example of a schematic exploded perspective view of one implementation of an electronic device having an optical MEMS display.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to methods of manufacturing an electromechanical systems (EMS) package that include EMS devices having an anti-stiction coating. The anti-stiction coating can prolong the life of the EMS device by reducing the sensitivity to moisture and organic contamination within the EMS device and its encapsulated cavity. In some implementations, the anti-stiction coating may be an out-gassable anti-stiction coating (also referred to as a releasable anti-stiction coating). An out-gassable anti-stiction coating can be out-gassed upon activation by one or more events. For example, some out-gassable anti-stiction coatings may be out-gassed upon exposure to particular temperatures or temperature profiles, or may be out-gassed more slowly even at room temperature. Other anti-stiction coatings may be out-gassed upon exposure to particular wavelengths of light or electromagnetic radiation. Still other out-gassable anti-stiction coatings may be out-gassed when exposed to other compounds, for example compounds in gaseous form.

In some implementations, the anti-stiction coating is out-gassed from within the EMS package after the package has been sealed. This application can be carried out, for example, by activating out-gassing of residual solvents that have anti-stiction properties. The residual solvents may be part of a desiccant formulation that was incorporated into the sealed device. Other compounds also may be included as part of the desiccant formulation without necessarily being solvents for the desiccant material.

In some implementations, the anti-stiction coating may be out-gassed by baking an EMS package, including an EMS device, to out-gas the anti-stiction material within the device. In this implementation, the EMS package is first manufactured with a releasable anti-stiction material, and then a post encapsulation bake cycle is used to out-gas at least a portion of the releasable anti-stiction material. In some implementations, the baking cycle out-gases the anti-stiction material which then becomes deposited via vapor diffusion onto surfaces within the encapsulated EMS package.

In some implementations, a desiccant mixture is baked using a first temperature profile to out-gas some, but not all, of the solvent within the desiccant mixture. This may help the desiccant adhere to a surface of the EMS package, and may reduce stiction in the EMS device. The mixture may be applied to a surface of an EMS package, with the desiccant mixture including desiccant material and solvent. The EMS package may then be encapsulated or sealed. In this implementation, following encapsulation, the sealed EMS package is baked a second time using a second temperature profile so that at least some of the remaining solvent in the desiccant is out-gassed to the interior of the EMS package.

In some implementations, the post encapsulation bake cycle may include an incubation bake of the sealed EMS package. An incubation bake cycle may be carried out, for example, for one day at 90° C. or for one week at 50° C. Other temperatures and times are also contemplated, as discussed below, so that the sealed EMS package is treated for enough time to allow a substantially complete vapor diffusion of the anti-stiction material throughout the EMS package. Generally, shorter incubation bake cycles may be used with higher temperatures, while lower temperatures may be used with longer incubation bake cycles. For example, in implementations wherein the desiccant is located around the periphery of an array of movable elements, an incubation bake may be performed so that out-gassable anti-stiction material within the EMS package has time to flow by vapor diffusion to the central portions of the array. Moreover, the incubation bake may improve uniformity of unwanted materials (such as leftover photoresist, unwanted particulates, and contaminants) throughout the EMS package, or panel of EMS packages. This more uniform distribution of unwanted materials may reduce their adverse effects by diffusing them over a larger area, such that no particular display elements are inordinately affected by a large concentration of these materials.

As discussed below, performing an incubation bake cycle has been found to reduce stiction of movable elements (such as an interferometric modulator (IMOD) movable layer) and thereby improved the lifetime of the EMS package. In some implementations, the incubation bake cycle may be performed separately from the post encapsulation bake cycle. In some other implementations, the incubation bake cycle may be performed at the same time as the encapsulation bake cycle.

Some implementations have one or more of the following potential advantages. Some of the described methods of manufacturing EMS packages allow simplification of traditional techniques for applying anti-stiction coatings within these devices. By using the disclosed methods, an anti-stiction coating can be applied on the EMS devices without requiring additional process steps to manufacture the EMS packages. For example, in one implementation, the anti-stiction coating is deposited on an EMS device by baking an EMS package with an integrated desiccant layer that was prepared with a solvent having anti-stiction properties. As the solvent evaporates out of the desiccant, it coats the interior surfaces of the EMS device. By using this process, no extra manufacturing steps may be required to place an anti-stiction coating within an EMS device. This has the potential to save capital investment and development lead time.

Other implementations may provide for increased lifetime of EMS packages by performing an incubation bake cycle after the EMS package is sealed. The incubation bake cycle may provide for improved distribution of anti-stiction material to the movable elements of an EMS package, including those elements located furthest from a desiccant that includes an out-gassable anti-stiction material. This improved distribution of anti-stiction material may enable the use of these devices in certain applications because of the longer life provided to these devices. Additionally, the incubation bake cycle may improve cosmetic yield, as well as manufacturing yield, since the improved distribution of anti-stiction material, and unwanted materials, may reduce the number of failed EMS devices per package, or per panel. Thus, incubation can improve package, or panel, stiction margin. It also may reduce associated warranty costs in other applications.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

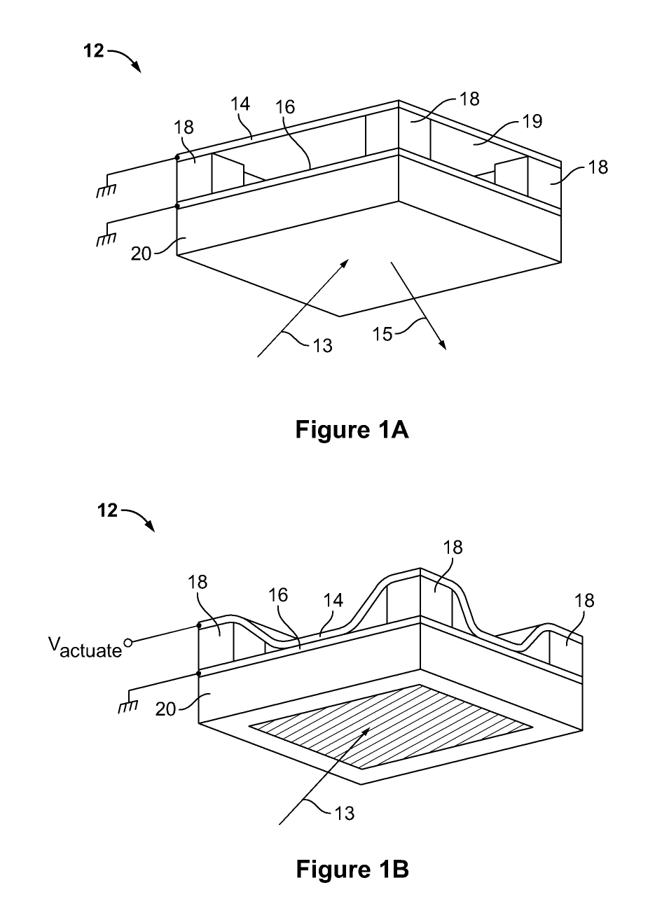

FIGS. 1A and 1B show examples of isometric views depicting a pixel of an interferometric modulator (IMOD) display device in two different states. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light, or ultra-violet light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted pixels in FIGS. 1A and 1B depict two different states of an IMOD 12. In the IMOD 12 in FIG. 1A, a movable reflective layer 14 is illustrated in a relaxed position at a (e.g., designed) distance from an optical stack 16, which includes a partially reflective layer. Since no voltage is applied across the IMOD 12 in FIG. 1A, the movable reflective layer 14 remained in a relaxed or unactuated state. In the IMOD 12 in FIG. 1B, the movable reflective layer 14 is illustrated in an actuated position and adjacent, or nearly adjacent, to the optical stack 16. The voltage V_{actuate} applied across the IMOD 12 in FIG. 1B is sufficient to actuate the movable reflective layer 14 to an actuated position.

In FIGS. 1A and 1B, the reflective properties of pixels 12 are generally illustrated with arrows 13 indicating light incident upon the pixels 12, and light 15 reflecting from the pixel 12. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixels 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals; e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the optical stack 16, or lower electrode, is grounded at each pixel. In some implementations, this may be accomplished by depositing a continuous optical stack 16 onto the substrate 20 and grounding at least a portion of the continuous optical stack 16 at the periphery of the deposited layers. In some implementations, a highly conductive and reflective material, such as aluminum (Al), may be used for the movable reflective layer 14. The movable reflective layer 14 may be formed as a metal layer or layers deposited on top of posts 18 and an intervening sacrificial material deposited and patterned between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 in FIG. 1A, with the gap 19 between the movable reflective layer 14 and optical stack 16. However, when a potential difference, e.g., voltage, is applied to at least one of the movable reflective layer 14 and optical stack 16, the capacitor formed at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 in FIG. 1B. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

In some implementations, such as in a series or array of IMODs, the optical stacks 16 can serve as a common electrode that provides a common voltage to one side of the IMODs 12. The movable reflective layers 14 may be formed as an array of separate plates arranged in, for example, a matrix form. The separate plates can be supplied with voltage signals for driving the IMODs 12.

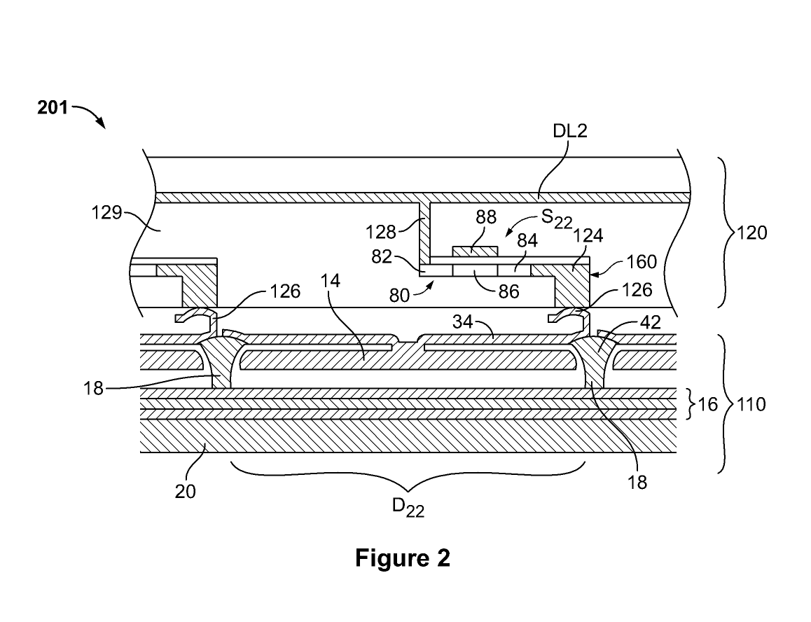

The details of the structure of interferometric modulators that operate in accordance with the principles set forth above may vary widely. For example, the movable reflective layers 14 of each IMOD 12 may be attached to supports at the corners only, e.g., on tethers. As shown in FIG. 2, a flat, relatively rigid movable reflective layer 14 may be suspended from a deformable layer 34, which may be formed from a flexible metal. This architecture allows the structural design and materials used for the electromechanical aspects and the optical aspects of the modulator to be selected, and to function, independently of each other. Thus, the structural design and materials used for the movable reflective layer 14 can be optimized with respect to the optical properties, and the structural design and materials used for the deformable layer 34 can be optimized with respect to desired mechanical properties. For example, the movable reflective layer 14 portion may be aluminum, and the deformable layer 34 portion may be nickel. The deformable layer 34 may connect, directly or indirectly, to the substrate 20 around the perimeter of the deformable layer 34. These connections may form the support posts 18.

In implementations such as those shown in FIGS. 1A and 1B, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 2) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing.

FIG. 2 is an example of a schematic partial cross-section illustrating one implementation of the structure of a driving circuit and an associated display element. A portion 201 of the driving circuit array 200 includes the switch S₂₂ at the second column and the second row, and the associated display element D₂₂. In the illustrated implementation, the switch S₂₂ includes a transistor 80. Other switches in the driving circuit array 200 can have the same configuration as the switch S₂₂, or can be configured differently, for example by changing the structure, the polarity, or the material.

FIG. 2 also includes a portion of a display array assembly 110, and a portion of a backplate 120. The portion of the display array assembly 110 includes the display element D₂₂. The display element D₂₂ includes a portion of a front substrate 20, a portion of an optical stack 16 formed on the front substrate 20, supports 18 formed on the optical stack 16, a movable reflective layer 14 (or a movable electrode connected to a deformable layer 34) supported by the supports 18, and an interconnect 126 electrically connecting the movable reflective layer 14 to one or more components of the backplate 120.

The portion of the backplate 120 includes the second data line DL2 and the switch S₂₂, which are embedded in the backplate 120. The portion of the backplate 120 also includes a first interconnect 128 and a second interconnect 124 at least partially embedded therein. The second data line DL2 extends substantially horizontally through the backplate 120. The switch S₂₂ includes a transistor 80 that has a source 82, a drain 84, a channel 86 between the source 82 and the drain 84, and a gate 88 overlying the channel 86. The transistor 80 can be, e.g., a thin film transistor (TFT) or metal-oxide-semiconductor field effect transistor (MOSFET). The gate of the transistor 80 can be formed by gate line GL2 extending through the backplate 120 perpendicular to data line DL2. The first interconnect 128 electrically couples the second data line DL2 to the source 82 of the transistor 80.

The transistor 80 is coupled to the display element D₂₂ through one or more vias 160 through the backplate 120. The vias 160 are filled with conductive material to provide electrical connection between components (for example, the display element D₂₂) of the display array assembly 110 and components of the backplate 120. In the illustrated implementation, the second interconnect 124 is formed through the via 160, and electrically couples the drain 84 of the transistor 80 to the display array assembly 110. The backplate 120 also can include one or more insulating layers 129 that electrically insulate the foregoing components of the driving circuit array 200.

The optical stack 16 of FIG. 2 is illustrated as three layers, a top dielectric layer described above, a middle partially reflective layer (such as chromium) also described above, and a lower layer including a transparent conductor (such as indium-tin-oxide (ITO)). The common electrode is formed by the ITO layer and can be coupled to ground at the periphery of the display. In some implementations, the optical stack 16 can include more or fewer layers. For example, in some implementations, the optical stack 16 can include one or more insulating or dielectric layers covering one or more conductive layers or a combined conductive/absorptive layer.

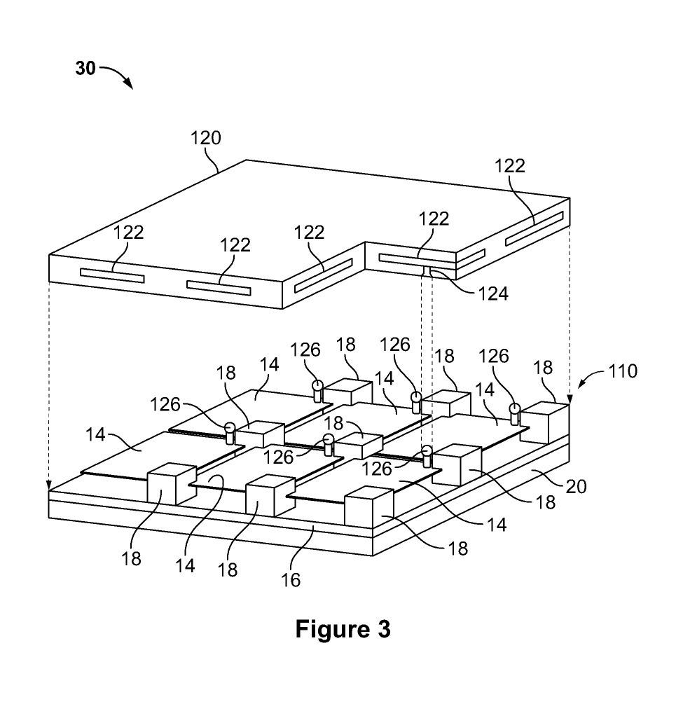

FIG. 3 shows an example of a schematic exploded partial perspective view of an optical MEMS display device having an interferometric modulator array and a backplate with embedded circuitry. The display device 30 includes a display array assembly 110 and a backplate 120. In some implementations, the display array assembly 110 and the backplate 120 can be separately pre-formed before being attached together. In some other implementations, the display device 30 can be fabricated in any suitable manner, such as, by forming components of the backplate 120 over the display array assembly 110 by deposition.

The display array assembly 110 can include a front substrate 20, an optical stack 16, supports 18, a movable reflective layer 14, and interconnects 126. The backplate 120 can include backplate components 122 at least partially embedded therein, and one or more backplate interconnects 124.

The optical stack 16 of the display array assembly 110 can be a substantially continuous layer covering at least the array region of the front substrate 20. The optical stack 16 can include a substantially transparent conductive layer that is electrically connected to ground. The reflective layers 14 can be separate from one another and can have, e.g., a square or rectangular shape. The movable reflective layers 14 can be arranged in a matrix form such that each of the movable reflective layers 14 can form part of a display element. In the implementation illustrated in FIG. 3, the movable reflective layers 14 are supported by the supports 18 at four corners.

Each of the interconnects 126 of the display array assembly 110 serves to electrically couple a respective one of the movable reflective layers 14 to one or more backplate components 122 (e.g., transistors S and/or other circuit elements). In the illustrated implementation, the interconnects 126 of the display array assembly 110 extend from the movable reflective layers 14, and are positioned to contact the backplate interconnects 124. In another implementation, the interconnects 126 of the display array assembly 110 can be at least partially embedded in the supports 18 while being exposed through top surfaces of the supports 18. In such an implementation, the backplate interconnects 124 can be positioned to contact exposed portions of the interconnects 126 of the display array assembly 110. In yet another implementation, the backplate interconnects 124 can extend from the backplate 120 toward the movable reflective layers 14 so as to contact and thereby electrically connect to the movable reflective layers 14.

The interferometric modulators described above are bi-stable display elements having two states: a relaxed state and an actuated state. The following description relates to analog interferometric modulators. For example, in one implementation of an analog interferometric modulator, a single interferometric modulator can reflect a red color, a green color, a blue color, a black color, and a white color. In some implementations, an analog interferometric modulator can reflect any color within a range of wavelengths of light depending upon an applied voltage. Further, the optical stack of the analog interferometric modulator may differ from the bi-stable display elements described above. These differences may produce different optical results. For example, in some implementations of the bi-stable elements described above, the closed (actuated) state gives the bi-stable element a dark (for example black) reflective state. In some implementations, the analog interferometric modulator reflects white light when the electrodes are in a position analogous to the closed state of the bi-stable element.

In some implementations, the packaging of an EMS component or device, such as an interferometric modulator-based display, can include a backplate (alternately be referred to as a backplane) which can be configured to protect the EMS component from damage (such as from mechanical interference or potentially damaging substances). The backplate also can provide structural support for a wide range of components, including but not limited to: driver circuitry, processors, memory, interconnect arrays, vapor barriers, product housing, and the like. In some implementations, the use of a backplate can facilitate integration of components and thereby reduce the volume, weight, and/or manufacturing costs of a portable electronic device.

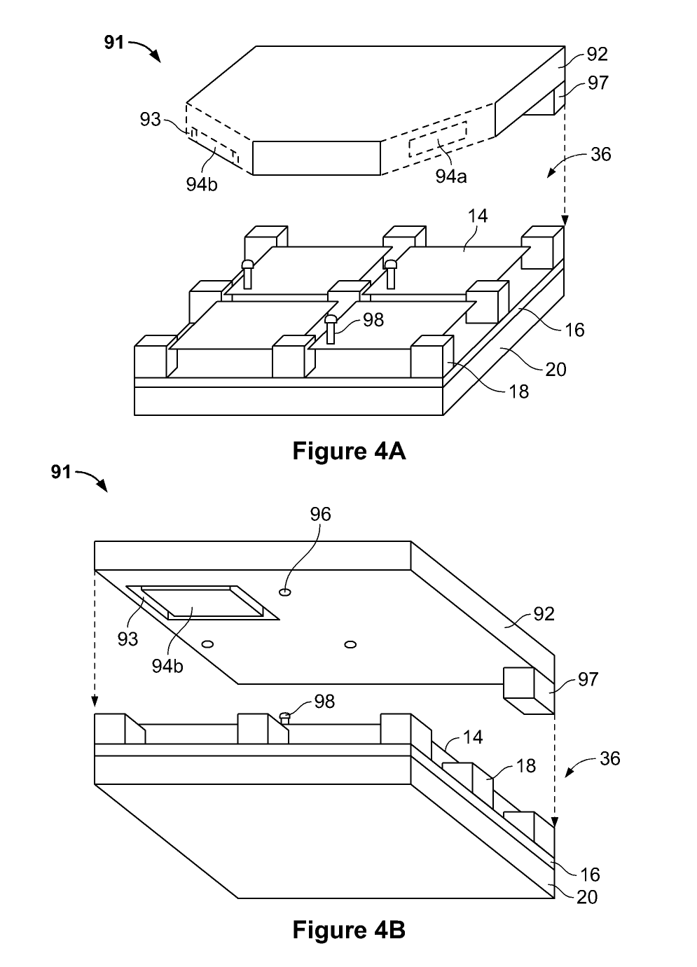

FIGS. 4A and 4B show examples of schematic exploded partial perspective views of a portion of an electromechanical systems (EMS) package including an array of electromechanical systems elements and a backplate. FIG. 4A is shown with two corners of the backplate 92 cut away to better illustrate certain portions of the backplate 92, while FIG. 4B is shown without the corners cut away. The array 36 can include a transparent substrate 20, an optical stack 16, support posts 18, and a movable reflective layer 14.

The backplate 92 can be essentially planar or can have at least one contoured surface (i.e., the backplate 92 can be formed with recesses and/or protrusions). The backplate 92 may be made of any suitable material, whether transparent or opaque, conductive or insulating. Suitable materials for the backplate 92 include, but are not limited to, glass, plastic, ceramics, polymers, laminates, metals and metal foils.

As shown in FIGS. 4A and 4B, the backplate 92 can include one or more backplate components 94a and 94b, which can be partially or wholly embedded in the backplate 92. As can be seen in FIG. 4A, the backplate component 94a is embedded in the backplate 92. As can be seen in FIG. 4B, the backplate component 94b is disposed within a recess 93 formed in a surface of the backplate 92. In some implementations, the backplate components 94a and/or 94b can protrude from a surface of the backplate 92. Although the backplate component 94a is disposed on the side of the backplate 92 facing the transparent substrate 20, in another implementation, the backplate components can be disposed on the opposite side of the backplate 92.

The backplate components 94a and/or 94b can include one or more active or passive electrical components, such as transistors, capacitors, inductors, resistors, diodes, switches, and/or integrated circuits. Other examples of backplate components that can be used in implementations include antennas, batteries, and sensors, such as electrical, optical, or chemical sensors.

In some implementations, the backplate components 94a and/or 94b can be in electrical communication with portions of the array 36. Conductive structures such as traces, bumps, posts, or vias may be formed on one or both of the backplate 92 or the substrate 20 and may contact one another or other conductive components to form electrical connections between the array 36 and the backplate components 94a and/or 94b. For example, the illustrated implementation includes vias 96 on the backplate 92 which can be aligned with electrical contacts 98 extending upward from the movable layers 14 within the array 36. In some implementations, the backplate 92 also can include one or more insulating layers that electrically insulate the backplate components 94a and/or 94b from other components of the array 36. In some implementations, such as implementations in which the backplate 92 is formed from vapor-permeable materials, an interior surface of backplate 92 can be coated with a vapor barrier (not shown).

The backplate components also can include one or more desiccants which act to absorb any moisture that may enter the EMS package 91. In some implementations, a desiccant may be provided separately from any other backplate components, for example as a sheet that is mounted to the backplate 92 (or to a recess formed therein) with adhesive. In other implementations, a desiccant may be applied directly or indirectly over other backplate components, for example by spray-coating, screen printing, or any other suitable method. In still other implementations, one or more desiccants may be positioned at the periphery of an EMS package. For example, some implementations provide a continuous desiccant ring that encircles an EMS device. In some other implementations, one or more desiccants may substantially encircle the EMS device.

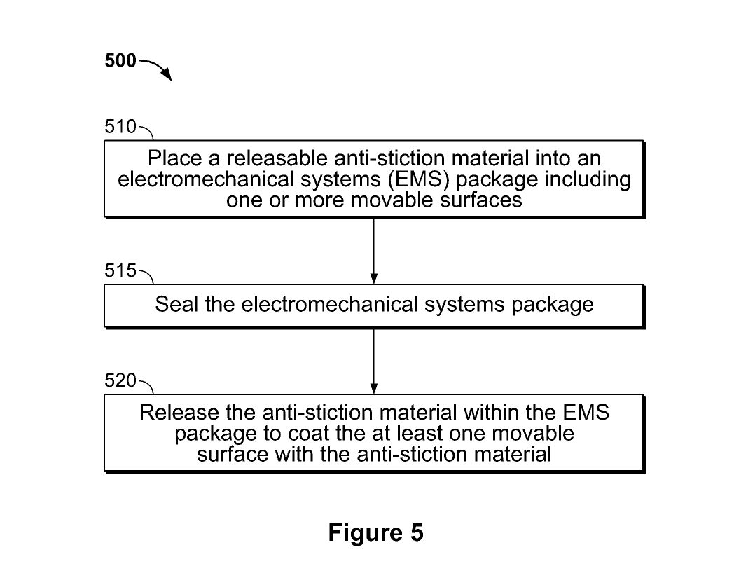

In some implementations, the array 36 and/or the backplate 92 can include mechanical standoffs 97 to maintain a distance between the backplate components and the display elements and thereby prevent mechanical interference between these components. In the implementation illustrated in FIGS. 5A and 5B, the mechanical standoffs 97 are formed as posts protruding from the backplate 92 in alignment with the support posts 18 of the array 36. Alternatively, or in addition, mechanical standoffs, such as rails or posts, can be provided along the edges of the EMS package 91. In implementations where a desiccant is provided around the periphery of the backplate 92 or substrate 20, the mechanical standoffs may be located more centrally within the EMS package 91 to prevent the mechanical standoffs from damaging the desiccant.

Although not illustrated in FIGS. 4A and 4B, a seal can be provided which partially or completely encircles the array 36. Together with the backplate 92 and the transparent substrate 20, the seal can form a protective cavity enclosing the array 36. The seal may be a semi-hermetic seal, such as a conventional epoxy-based adhesive. In some other implementations, the seal may include polyisobutylene (PIB), polyurethane, liquid spin-on glass, solder, polymers, plastics, or other materials. In some implementations, a reinforced sealant can be used to form mechanical standoffs. In some other implementations, the seal may be a hermetic seal, such as a thin film metal weld or a glass frit.

In alternate implementations, a seal ring may include an extension of either one or both of the backplate or transparent substrate. For example, the seal ring may comprise a mechanical extension (not shown) of a backplate. In still other implementations, the seal ring may include a separate member, such as an o-ring or other annular member.

In some implementations, the array 36 and the backplate 92 are separately formed before being attached or coupled together. For example, the edge of a transparent substrate 20 can be attached and sealed to the edge of the backplate 92 as described above. In some other implementations, the EMS package 91 can be fabricated in any other suitable manner, such as by forming components of the backplate 92 over the array 36 by deposition.

FIG. 5 illustrates a method 500 for making an EMS package. In block 510 of process 500, an out-gassable anti-stiction material is placed into an EMS package having one or more movable surfaces. The movable surfaces may be part of an EMS device included within the EMS package. For example, the movable surfaces may correspond to movable reflective layer 14 or optical stack 16 of FIG. 2. The anti-stiction material may be out-gassed by exposure to a particular temperature or temperature profile. The anti-stiction material also may be out-gassed when exposed to particular wavelengths of light or other form of electromagnetic radiation. In block 515, the EMS package is sealed. In block 520 the anti-stiction material is out-gassed within the EMS package to coat the at least one movable surface with the anti-stiction material. As discussed below, the anti-stiction material may be out-gassed utilizing a variety of methods.

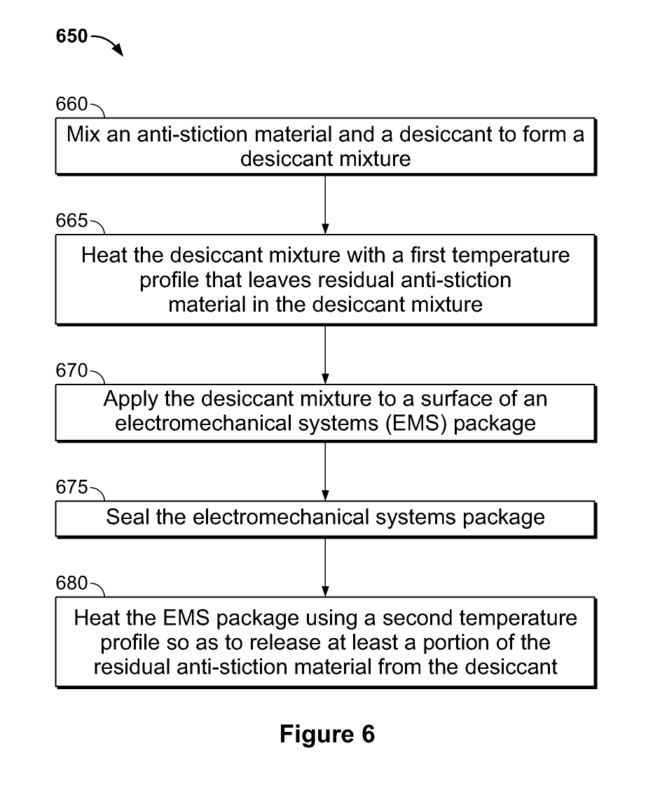

FIG. 6 illustrates another method for making an EMS package. In block 660 of the process 650, an anti-stiction material and a desiccant are mixed to form a desiccant mixture. In some implementations, the anti-stiction material may be a linear, branched, or cyclic non-polar hydrocarbon with 20 or less carbon atoms. The anti-stiction material also may be an isoparaffinic solvent. The process 650 then moves to block 665, wherein the desiccant mixture is heated using a first temperature profile that leaves residual anti-stiction material in the desiccant mixture. Depending on the anti-stiction material utilized, the first temperature profile may vary. For example, when using an isoparaffinic solvent as an anti-stiction material, the first temperature profile may include a range of temperatures between 90° C. and 120° C. In some implementations, the oven may be allowed to naturally cool after reaching a peak temperature.

In block 670, the desiccant mixture is applied to a surface of an EMS package. In some implementations, the desiccant may be applied to a backplate of the EMS package. Alternatively, a backplate may include a cavity, with the desiccant applied within the cavity. In some other implementations, a desiccant ring may be deposited on the backplate of the EMS package. In some implementations, the desiccant ring may be deposited onto the backplate in a configuration that substantially surrounds an EMS device within the EMS package. In some other implementations, one or more desiccant patches may be positioned on the backplate. These patches also may substantially surround an EMS device in some implementations. The backplate of the EMS package may be made of glass, plastic, polymeric resins or other materials suitable for this purpose.

In block 675, the EMS package is sealed. In block 680, the EMS package is heated using a second temperature profile so as to out-gas at least a portion of the residual anti-stiction material from the desiccant. Some implementations may use a second temperature profile with a temperature between 90° C. and 120° C. At these temperatures, an incubation time of at least 24 hours may provide for distribution of anti-stiction material to the display elements included in the EMS package, including those elements furthest from a desiccant with out-gassable anti-stiction material.

In some other implementations, lower temperatures may be used. For example, some implementations may incubate an EMS package for 3, 4, 5, 6, 7 days or as long as one week or more at a lower temperature, such as 25-50° C.

In some implementations, the maximum temperature for the incubation bake of the EMS package may be limited. Some materials used to manufacture the EMS package may not tolerate temperatures higher than a threshold. For example, certain adhesives used to seal the EMS package may begin outgassing contaminants above a temperature of 100° C. These contaminants may contaminate the individual display devices within the EMS package, shortening their life. Other implementations may include materials that do not exhibit these limitations at high temperatures.

Accordingly, the process 650 allows the manufacture of an EMS package that has an integrated anti-stiction coating provided by baking residual anti-stiction material out of an applied desiccant mixture.

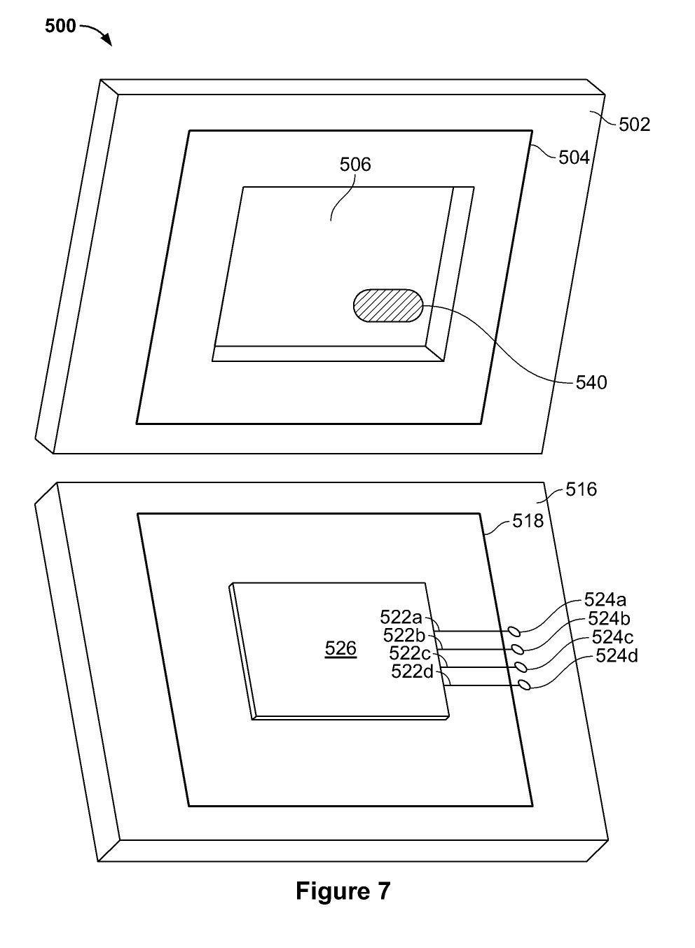

FIG. 7 shows a perspective view of an EMS package including a desiccant within a sealed enclosure formed by a backplate and a substrate. The EMS package 500 includes a desiccant 540 within a sealable enclosure formed by a backplate 502 and a substrate 516. In some implementations, the backplate 502 is an etchable, transparent substrate, such as plastic or glass. In some implementations, the backplate 502 is a deposited thin film layer instead of plastic or glass. For example, the backplate 502 may be a thin film encapsulation layer. In some implementations, the backplate 502 can be semi-transparent or opaque.

As shown, the backplate 502 includes a recess 506 that may be wet etched into the backplate or formed through other appropriate means to produce the recess 506 in the backplate 502. In some implementations, the recess 506 may have a depth of 100-200 microns. In some implementations, the recess 506 may have a depth less than 100 microns. In some implementations, the recess 506 may have a depth greater than 200 microns. In some implementations, the recess 506 is generally concave in shape, including a flat portion at the apex. According to some other implementations, the backplate 502 may include more than one of cavities 506.

FIG. 7 shows an implementation with a recess 506 having a generally square shape. In another implementation, the recess 506 may be round, rectangular or irregular in shape. In some implementations there is a more than one recess in the backplate 502.

In some implementations, a desiccant 540 can be configured within the recess 506. The desiccant 540 may be placed in the cavity 506 so as to assist with control of the environment of the enclosure during the life of the EMS package. In some implementations, the desiccant 540 may be formed by first mixing an active desiccation ingredient, for example Calcium Oxide powder, with an anti-stiction material, for example, an isoparaffinic solvent. Other anti-stiction materials that may be mixed with a desiccant are also contemplated, and may include any linear, branched, or cyclic non-polar hydrocarbon. In some implementations, the linear, branched, or cyclic non-polar hydrocarbons have 20 or fewer carbon atoms.

The EMS device 526, desiccant 540 and recess 506 are surrounded by a sealing ring 504. The sealing ring 504 may be formed on the backplate 502 by administration of an adhesive or other sealant that seals the backplate 502 to the substrate 516. In one aspect, a sealing ring 518 also can be applied to the substrate 516, and the combined sealing rings 504 and 518 can be joined to provide a protective enclosure for the elements contained within the EMS package 500. In some implementations, the sealing ring 504 or the sealing ring 518 maintains a controlled atmosphere inside the EMS package 500. In some implementations, the sealing ring 504 and/or the sealing ring 518 forms a hermetic seal.

The EMS device 526 can be in electrical communication with conductive traces 522a-d extending across the sealing ring 518 to a set of connection pads 524a-d. Once the backplate 502 is joined to the substrate 516, the pads 524a-d are disposed external to the chamber created by the combination of the sealing rings 504 and 518. By running the conductive traces under the sealing ring 518 to the pads 524a-d, the EMS package 500 can be coupled to other external components at the connection pads 524a-d without breaching the hermeticity of the sealed package.

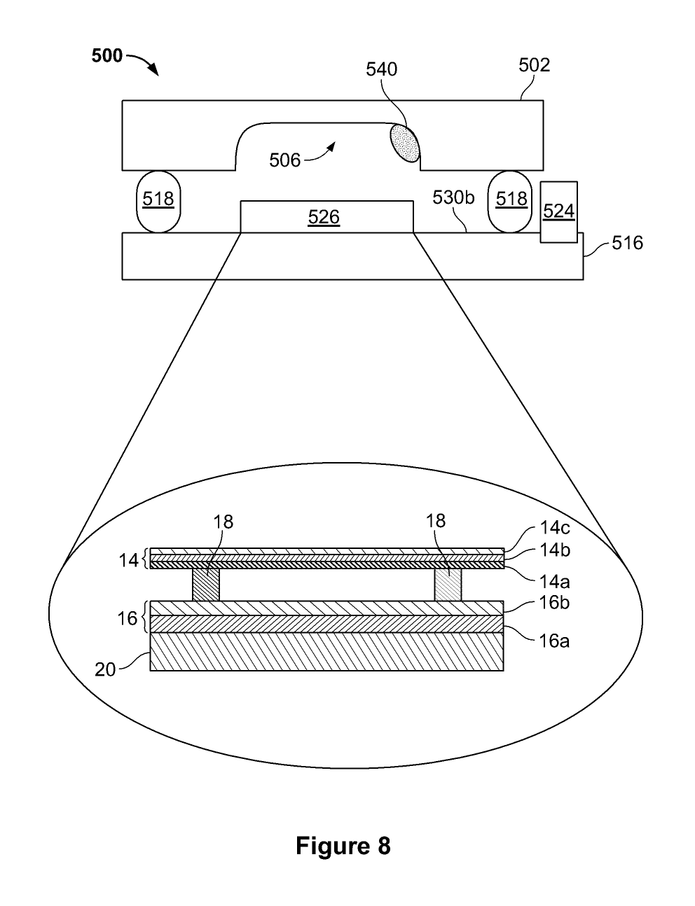

FIG. 8 shows a cross-sectional view of an assembled EMS package employing a desiccant within a sealed enclosure, with the desiccant including out-gassable anti-stiction material. The desiccant 540 in FIG. 8 is shown prior to out-gas of the anti-stiction material into the interior of the EMS package 500. As shown, the EMS package 500 includes the backplate 502 having the recess 506 as discussed above. The completed assembly in FIG. 8 shows a sealed EMS package 500 where the backplate 502 is hermetically joined to the substrate 516 using the sealing ring 518 The sealing ring 518 forms a hermetic barrier separating the inside of the package from the outside. As shown, the enclosure formed by the backplate 502 and substrate 516 includes the EMS device 526. Although the desiccant 540 is shown as being positioned within the recess 506 of the backplate 502, it should be realized that the desiccant can be positioned outside the recess 506, or adhered to a backplate that has no recess.

FIG. 8 also illustrates an expanded view of the EMS device 526, with a portion of the optical stack 16 formed on the substrate 20. As discussed above with reference to FIG. 2, the supports 18 are formed on the optical stack 16 and support the movable reflective layer 14. As illustrated in FIG. 8, the anti-stiction coating still resides within the desiccant 540 and has not been out-gassed within the EMS package 500.

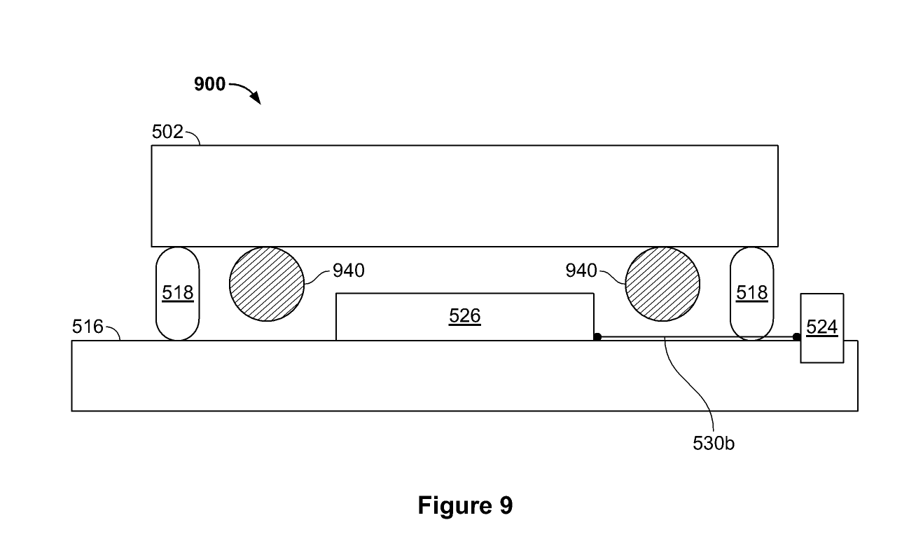

FIG. 9 shows another cross-sectional view of one implementation of the assembled EMS package employing a desiccant with out-gassable anti-stiction material within a sealed enclosure. In the EMS package 900, the desiccant 940 can be arranged at a plurality of locations on backplate 502. However, in some implementations, the desiccant 940 may be arranged as a continuous or discontinuous desiccant ring that is positioned above the EMS devices and adhered to the backplate. In this implementation, the desiccant ring 940 circumscribes the outer periphery of the EMS device 526. In FIG. 9, the desiccant 940 is shown prior to out-gassing of the anti-stiction material into the interior of the EMS package 900. The completed assembly in FIG. 9 shows a sealed EMS package where the backplate 502 is hermetically joined to the substrate 516 using the sealing ring 518.

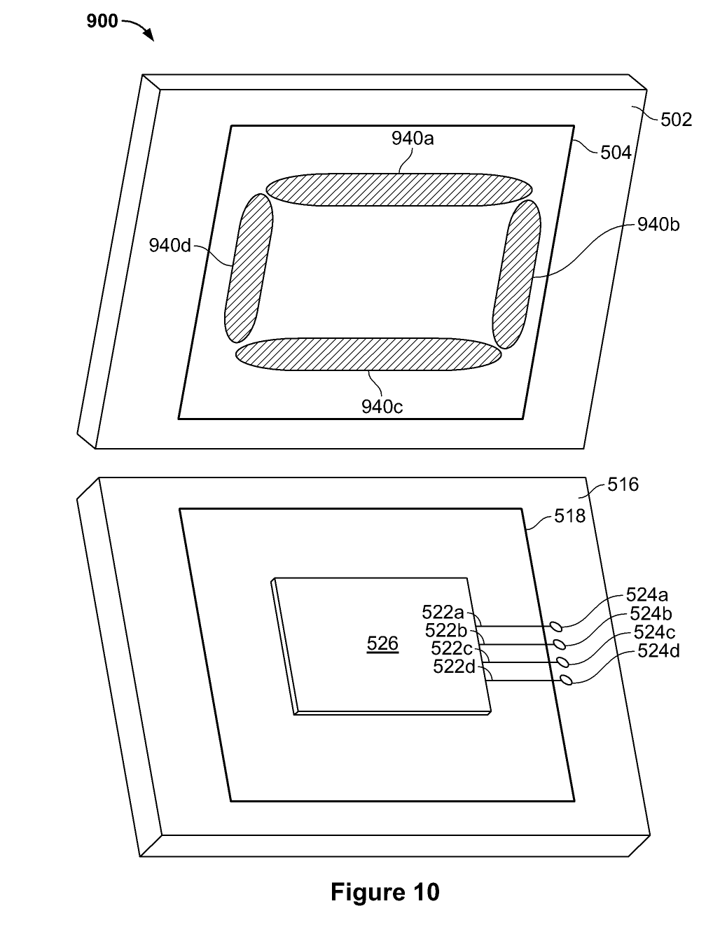

FIG. 10 shows a perspective view of an EMS package including a desiccant ring on a backplate that is configured to attach to a substrate. In the implementation illustrated in FIG. 10, several separate desiccant patches 940a-d are positioned on the backplate 502 so they become positioned around the periphery of the EMS device 526 when the device package 900 is sealed. In some implementations, the desiccant may be a continuous ring instead of discrete desiccant patches as shown in FIG. 10. In alternative implementations, a desiccant patch or desiccant ring may be positioned on the substrate 516, instead of on the backplate 502.

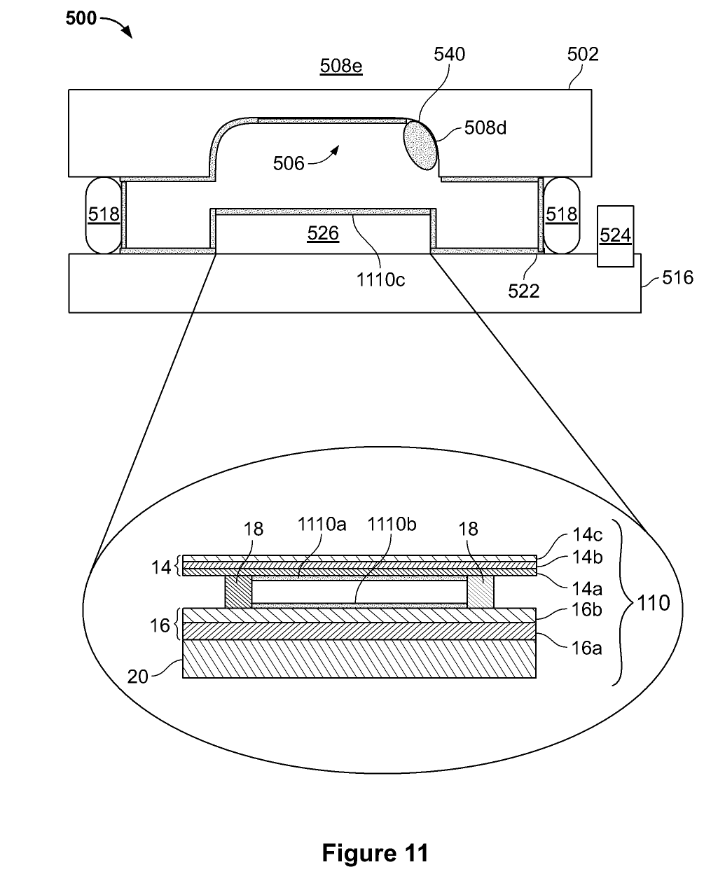

FIG. 11 shows a cross-sectional view of an EMS package after an anti stiction material has been out-gassed from a desiccant. In some implementations, the anti-stiction material has been out-gassed by completion of a post-sealing bake cycle. The bake cycle may include heating the EMS package 500 utilizing one or more temperature profiles so as to out-gas at least a portion of the residual anti-stiction material from the desiccant 540. As illustrated in FIG. 11, some of the residual anti-stiction material 1110 has been out-gassed from the desiccant and forms an anti-stiction layer 1110c on interior surfaces of the EMS package 500.

As can be seen in the expanded view of display array assembly 110 in FIG. 11, when compared to the expanded view shown in FIG. 8, the anti-stiction coating 1110 has coated the movable reflective layer 14 and optical stack 16 with anti-stiction coating layers 1110a and 1110b, respectively. The anti-stiction material formed anti-stiction coating layers 1110a, 1110b within the EMS device 526 to prevent the movable reflective layer 14 from adhering to the optical stack 16.

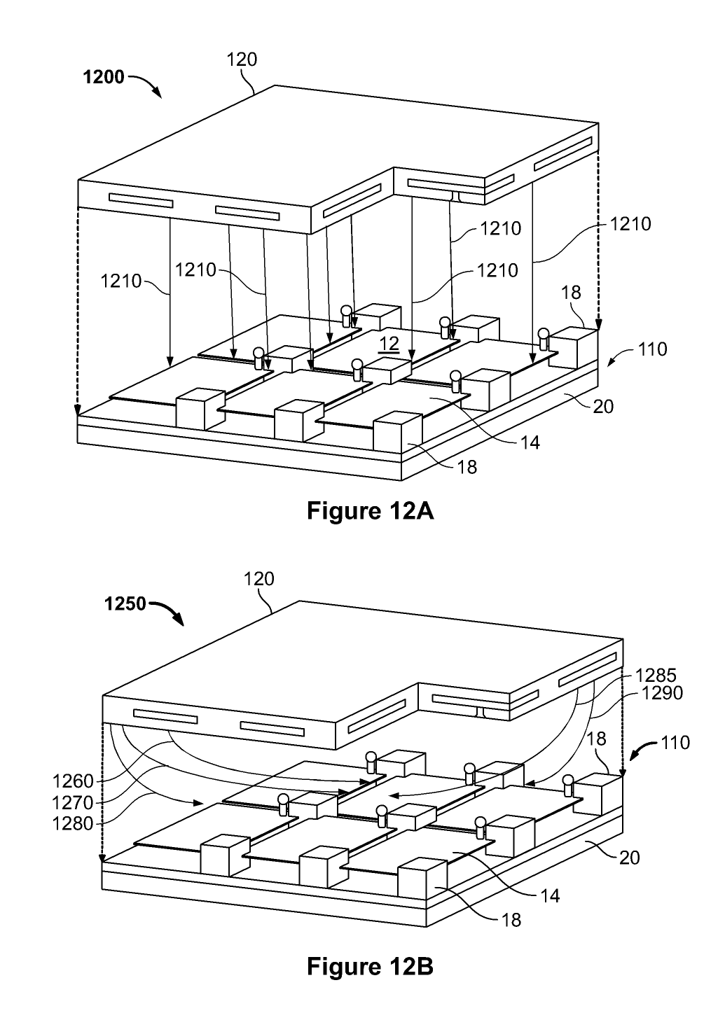

FIGS. 12A and 12B show exploded views of an EMS package that detail the vapor paths of out-gassable anti stiction material from a desiccant (not shown) on a backplate to a substrate within an EMS package. The vapor paths are depicted moving onto movable layers of the substrate within an EMS package 1200. When the anti-stiction material is out-gassed from the desiccant in the sealed EMS package, the gaseous anti-stiction material may be distributed from the desiccant (not shown) to the reflective layer 14 via a vapor path 1210 between the desiccant and reflective layer 14. Depending on the location of the desiccant, the length of the vapor path from the desiccant or series of desiccants to each movable element may vary. For example, FIG. 12A illustrates that the vapor paths 1210 within the EMS package 1200 include a desiccant or desiccants positioned across the underside surface of the backplate 120. In the illustrated example, vaporized anti-stiction material distributes directly from the desiccant (not shown) located on the backplate 120 to the movable reflective layers 14 via vapor paths 1210.

FIG. 12B shows an implementation wherein the desiccant with out-gassable anti-stiction material is positioned around the periphery of an EMS package 1250. In the illustrated implementation, the peripheral desiccant is positioned on the underside surface of the backplate 120. As shown, the vapor paths 1260-1290 between the desiccant (not shown) and the movable reflective layers 14 may be of varying length because the desiccant is located further or closer to different movable layers. For example, vapor path 1280 is shorter than vapor path 1260.

As explained below with reference to Example 1, it was discovered that performing a specific incubation bake after sealing the package led to a smoother and more uniform coating of anti-stiction material on the movable elements within the EMS package. Thus, by using the incubation bake, the anti-stiction material out-gassed from the desiccant was found to coat movable elements on the periphery and the center of the EMS package even if the desiccant was only located in peripheral positions with respect to the movable elements. When an incubation bake was not performed, or performed at lower temperatures or for shorter times, it was discovered that the anti-stiction material may be deposited in higher quantities or thicknesses on the movable elements located closer to the desiccant, and in smaller quantities or lower thicknesses to the movable elements located further from the desiccant. However, choosing the appropriate post packaging incubation baking process was found to reduce or eliminate this issue and allow for a more even anti-stiction coating onto the display elements within the EMS package.

An incubation baking process may have other benefits. For example, an incubation bake may distribute contaminants evenly throughout the EMS enclosure. This more even distribution of contaminants may reduce the adverse impact caused by the contaminants. For example, by distributing the contaminants more evenly throughout the EMS enclosure, no particular EMS device may be inordinately affected by contaminants. Because the contaminants are dispersed their negative effect on any particular EMS device is reduced.

Incubation bakes may be performed for a variety of times and temperatures (some of which may be predetermined) to allow the anti-stiction material from the desiccant to flow along internal vapor paths within the EMS package. In some implementations, the baking temperature may be from 25° C. to 120° C. In some other implementations, the baking temperature may be from 25° C. to 50° C., 50° C. to 75° C., or 90° C. to 120° C. In general, as the temperature is raised, the incubation baking time can be decreased. Thus, in one implementation, the incubation bake is performed at 50° C. for one week. In another implementation, the incubation bake is performed at 90° C. for one day. Of course, other combinations of baking times, such as 2, 3, 4, 5, 6, 7, 8, 9, 10 or more days are contemplated. In addition, other combinations of baking temperatures and baking times are contemplated, such as an incubation bake at less than 50° C. for more than one week, or an incubation bake at more than 90° C. for less than one day.

In some implementations, the incubation bake is performed so that a certain percentage of the anti-stiction coating material in the desiccant is out-gassed into the EMS package. Thus, one implementation is an incubation bake that is performed such that 60, 65, 70, 75, 80, 85, 90, 95, 96, 97, 98, 99, or 100 percent of the anti-stiction material is out-gassed from the desiccant.

In some other implementations, the incubation bake is performed so a certain percentage of the surface area within the EMS package is evenly covered by anti-stiction material. Thus, the incubation bake may be performed such that 75, 80, 85, 90, 95, 96, 97, 98, 99 or 100 percent of the available surface area within the EMS package that has an accessible vapor path from the desiccant becomes covered with anti-stiction material.

An experiment was performed to determine the effect of differing incubation bakes on the performance and stiction rate of an EMS package that contained an array of interferometric modulators. As shown below, the incubation bake process heated the EMS package, including the interferometric display elements to a predetermined temperature profile to evenly distribute the anti-stiction material within the EMS package.

Table 1 shows the results of testing EMS packages at higher than room temperature (i.e., 70° C.) or room temperature following different incubation baking conditions. In Experiments 1 and 2, one set of panels were incubated at 100° C. for one day. The control packages were not subject to an incubation bake. The results of are shown below in Table 1. After baking, the packages were tested by cycling the interferometric modulators within the package until failure, wherein stiction of the modulators substantially degraded the performance of the modulator array.

TABLE 1

| Exp. # | Test | Test Case | Improvement |
|---|---|---|---|
| 1 | 70° C. High | Control | |
| | Temperature | Incubation @ 90° C.- | 2.1X |
| | Operation | 120° C. for 24 hours | |
| 2 | Room | Control | |
| | Temperature | Incubation @ 90° C.- | 1.8X |
| | Operation | 120° C. for 24 hours | |

As shown in Table 1, the panels that included an incubation bake cycle had improved lifetimes when compared to the control panels at both high temperature and room temperature operations. Accordingly, in some implementations, the use of an incubation bake can increase the mean time to failure by approximately three fold under high temperature operations, and almost two-fold during room temperature operations.

In some implementations, the incubation bake process may include a temperature profile above 50° C. and less than or equal to 120° C. Temperatures above 100° C. may cause materials used in the manufacture of the panel to outgas contaminants that result in degradation of the life of display elements within the EMS package. For example, adhesives used to seal the EMS package may outgas contaminants with temperature profiles over 100° C. Aspects utilizing adhesives that are stable above 100° C. and do not outgas contaminants above those temperatures may benefit from incubation bake cycles that include temperatures above 100° C.

When utilizing an incubation cycle of 100° C., bake cycles of at least one day were found to reduce failure rates of display elements located furthest from the desiccant. When utilizing an incubation cycle of 50° C., incubation bake cycles of at least one week were found to reduce the failure rates of display elements located furthest from desiccants.

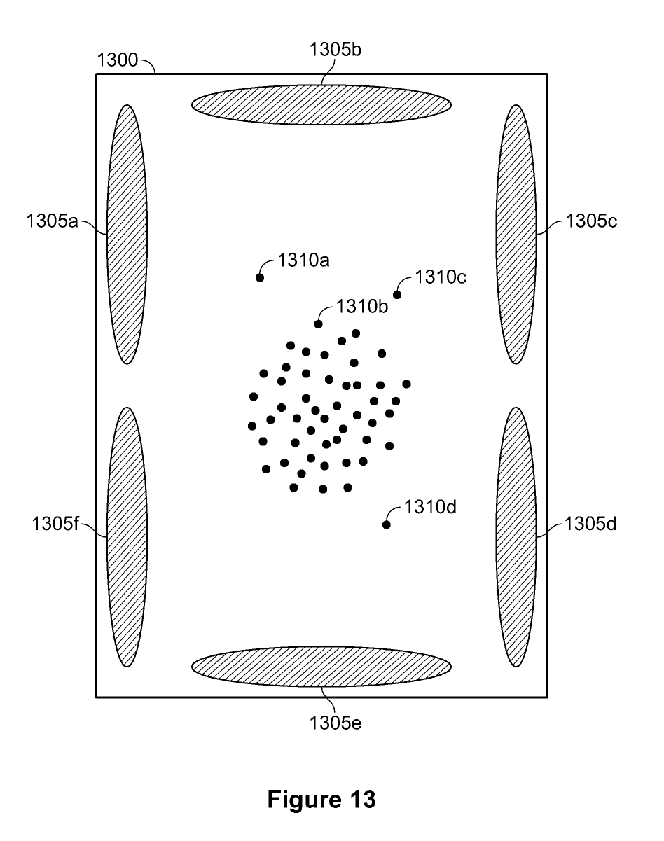

FIG. 13 shows a top view illustration of an EMS package that has desiccant material arranged around the periphery of the EMS package and was not treated after packaging to reduce stiction.

Following packaging, the EMS package 1300 was not baked and thus shows a pattern of dark circles 1310a-d that indicate the central location within the panel of display elements that failed due to stiction. As illustrated in FIG. 13, display elements located further from a desiccant patch 1305 a-f were found to have a higher failure rate due to the greater distance of the vapor path from the desiccant to the display elements. These failed display elements have a higher probability of being located in the center of the EMS package, given the center of EMS package is furthest from the desiccants 1305 positioned around the periphery of the EMS package 1300.

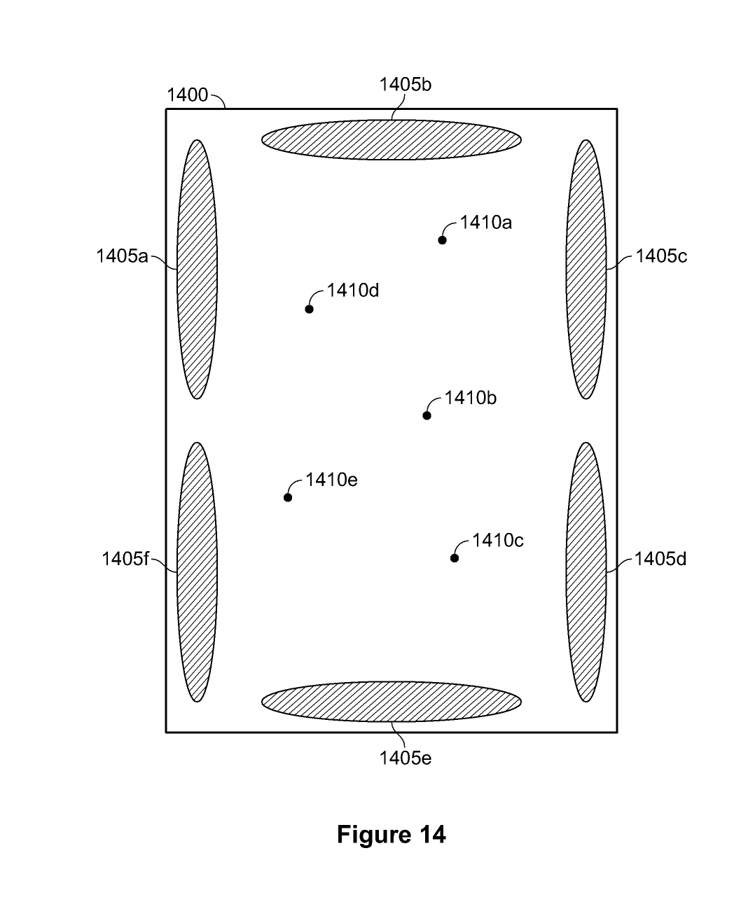

FIG. 14 shows a top view illustration of an EMS package that has desiccant material arranged around the periphery of the EMS package and was treated after packaging to improve distribution of anti-stiction material. The quantity of display element failures 1410a-d is reduced as compared to the EMS package illustrated in FIG. 13. While some failures, indicated as positions 1410a-d may occur, these failures are more randomly distributed across display elements, indicating the distribution of anti-stiction material was improved when compared to the test results illustrated in FIG. 13.

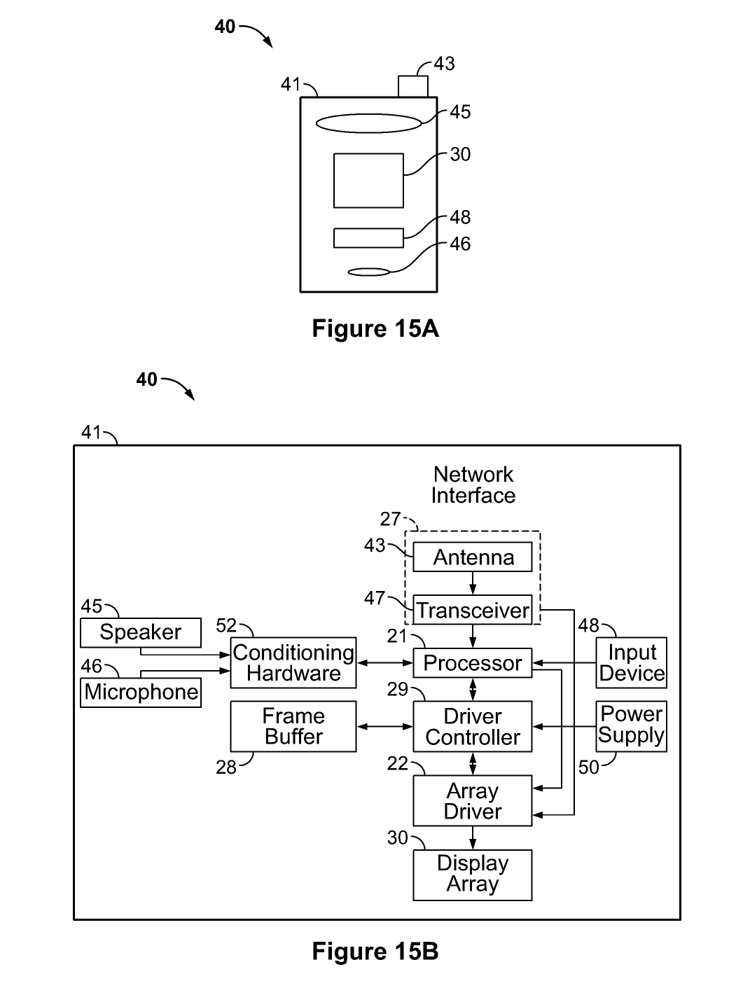

FIGS. 15A and 15B show examples of system block diagrams illustrating a display device 40 that includes a plurality of interferometric modulators. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 15B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

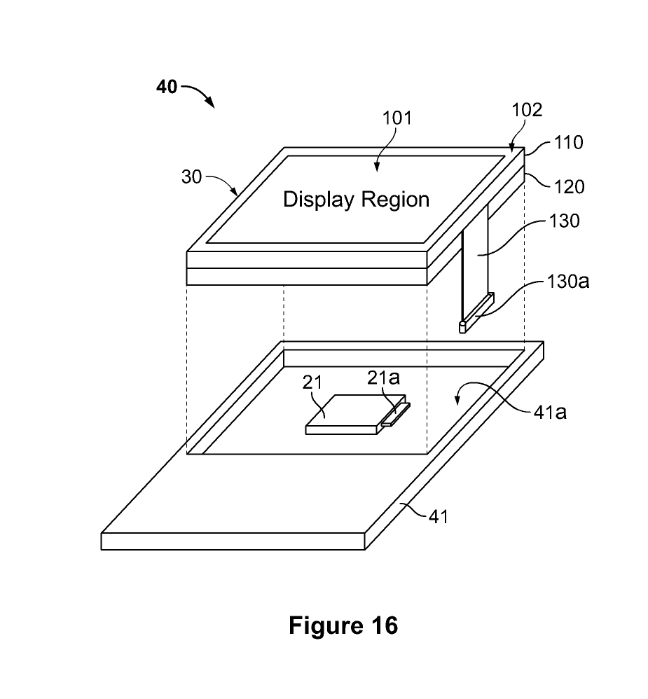

FIG. 16 is an example of a schematic exploded perspective view of the electronic device 40 of FIGS. 15A and 15B according to one implementation. The illustrated electronic device 40 includes a housing 41 that has a recess 41a for a display array 30. The electronic device 40 also includes a processor 21 on the bottom of the recess 41a of the housing 41. The processor 21 can include a connector 21a for data communication with the display array 30. The electronic device 40 also can include other components, at least a portion of which is inside the housing 41. The other components can include, but are not limited to, a networking interface, a driver controller, an input device, a power supply, conditioning hardware, a frame buffer, a speaker, and a microphone, as described earlier in connection with FIG. 15B.

The display array 30 can include a display array assembly 110, a backplate 120, and a flexible electrical cable 130. The display array assembly 110 and the backplate 120 can be attached to each other, using, for example, a sealant.

The display array assembly 110 can include a display region 101 and a peripheral region 102. The peripheral region 102 surrounds the display region 101 when viewed from above the display array assembly 110. The display array assembly 110 also includes an array of display elements positioned and oriented to display images through the display region 101. The display elements can be arranged in a matrix form. In some implementations, each of the display elements can be an interferometric modulator. Also, in some implementations, the term “display element” may be referred to as a “pixel.”

The backplate 120 may cover substantially the entire back surface of the display array assembly 110. The backplate 120 can be formed from, for example, glass, a polymeric material, a metallic material, a ceramic material, a semiconductor material, or a combination of two or more of the foregoing materials, in addition to other similar materials. The backplate 120 can include one or more layers of the same or different materials. The backplate 120 also can include various components at least partially embedded therein or mounted thereon. Examples of such components include, but are not limited to, a driver controller, array drivers (for example, a data driver and a scan driver), routing lines (for example, data lines and gate lines), switching circuits, processors (for example, an image data processing processor) and interconnects.

The flexible electrical cable 130 serves to provide data communication channels between the display array 30 and other components (for example, the processor 21) of the electronic device 40. The flexible electrical cable 130 can extend from one or more components of the display array assembly 110, or from the backplate 120. The flexible electrical cable 130 can include a plurality of conductive wires extending parallel to one another, and a connector 130a that can be connected to the connector 21a of the processor 21 or any other component of the electronic device 40.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but is to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of making an electromechanical systems (EMS) package having an anti-stiction coating, comprising:
placing an out-gassable anti-stiction material into the EMS package, the EMS package having at least one movable surface;
sealing the EMS package; and
releasing the anti-stiction material within the EMS package to coat the at least one movable surface with the anti-stiction material.

2. The method of claim 1, wherein placing an out-gassable anti-stiction material into the EMS package includes placing a desiccant into the EMS package.

3. The method of claim 2, wherein the desiccant includes the out-gassable anti-stiction material.

4. The method of claim 2, wherein the anti-stiction material is a solvent for the desiccant.

5. The method of claim 2, wherein the method includes heating the desiccant with a first temperature profile to leave residual anti-stiction material in the desiccant mixture.

6. The method of claim 1 wherein releasing the anti-stiction material includes heating the device package using a second temperature profile that causes out-gassing of at least a portion of anti-stiction material from the desiccant.

7. The method of claim 1, wherein the out-gassable anti-stiction material is a linear, branched, or cyclic non-polar hydrocarbon with 20 or less carbon atoms.

8. The method of claim 7, wherein the anti-stiction material is an isoparaffinic solvent.

9. The method of claim 3, wherein the out-gassable anti-stiction material is a linear, branched, or cyclic non-polar hydrocarbon with 20 or less carbon atoms.

10. The method of claim 3, wherein the anti-stiction material is an isoparaffinic solvent.

11. The method of claim 1, wherein releasing the anti-stiction material within the EMS package includes an incubation bake at between of 90° C. and 120° C. for at least 24 hours.

12. The method of claim 1, wherein releasing the anti-stiction material within the EMS package includes an incubation bake of between 50° C. and 75° C. for at least 48 hours.

13. The method of claim 1, wherein releasing the anti-stiction material within the EMS package includes an incubation bake configured to out-gas at least 90% of the anti-stiction material in the desiccant.

14. An electromechanical systems (EMS) package, comprising:
a sealed enclosure;
an electromechanical systems device within the sealed enclosure;
a desiccant composition including a solvent having anti-stiction properties when vaporized.

15. The EMS package of claim 14, wherein the desiccant is a baked desiccant that has out-gassed a portion of the solvent.

16. The EMS package of claim 14, wherein the solvent is a non-polar hydrocarbon.

17. The EMS package of claim 14, wherein the sealed enclosure includes a backplate, and wherein the desiccant is attached to the backplate.

18. The EMS package of claim 17, wherein the desiccant is deposited within a cavity in the backplate.

19. The EMS package of claim 17, wherein the desiccant is deposited on the backplate in a ring configuration.

20. An electromechanical systems (EMS) package, comprising:
a sealed enclosure;
a desiccant within the sealed enclosure; and
an EMS device within the sealed enclosure, the EMS device having at least one movable member, wherein the at least one movable member is coated with an anti-stiction coating formed from vaporizing a solvent included in a desiccant.

21. The EMS package of claim 20, wherein the solvent is a non-polar hydrocarbon.

22. The EMS package of claim 20, wherein the sealed enclosure includes a backplate, and wherein the desiccant is attached to the backplate.

23. The EMS package of claim 22, wherein the backplate has a cavity and wherein the desiccant is deposited within the cavity.

24. The EMS package of claim 22, wherein the desiccant is deposited on the backplate as a ring that surrounds the EMS device.

25. The EMS package of claim 20, further comprising:
a display;
a processor that is configured to communicate with the display, the processor being configured to process image data; and
a memory device that is configured to communicate with the processor.

26. The EMS package of claim 24, further comprising:
a driver circuit configured to send at least one signal to the display; and
a controller configured to send at least a portion of the image data to the driver circuit.

27. The EMS package of claim 24, further comprising:
an image source module configured to send the image data to the processor, wherein the image source module includes at least one of a receiver, transceiver, and transmitter.

28. The EMS package of claim 24, further comprising:
an input device configured to receive input data and to communicate the input data to the processor.

29. The electromechanical systems (EMS) package of claim 20, wherein the solvent was vaporized by an incubation bake of between 90° C. and 120° C. for at least 24 hours.

30. The electromechanical systems (EMS) package of claim 20, wherein the solvent was vaporized by an incubation bake of between 50° C. and 75° C. for at least 48 hours.

31. The electromechanical systems (EMS) package of claim 20, wherein contaminants within the EMS package are distributed by an incubation bake cycle.

32. An electromechanical systems (EMS) package, comprising:
a sealed enclosure;
an EMS device within the sealed enclosure; and
means for releasing a solvent having anti-stiction properties into the sealed enclosure.

33. The EMS package of claim 32, wherein the means for releasing a solvent is a desiccant.

34. The EMS package of claim 33, wherein the solvent is a non-polar hydrocarbon.

35. The EMS package of claim 32, wherein the means for releasing is configured to release solvent during an incubation bake of between 50° C. and 75° C. for at least 48 hours.

36. The EMS package of claim 32, wherein the means for releasing is configured to release solvent during an incubation bake of between 90° C. and 120° C. for at least 24 hours.

37. The electromechanical systems (EMS) package of claim 32, wherein contaminants within the EMS package are distributed by an incubation bake cycle.
